(19) United States
(12) Patent Application Publication
(10) Pub. No.: US 2015/0097762 A1
(43) Pub. Date: Apr. 9, 2015

(54) PIXEL AND ORGANIC LIGHT EMITTING DISPLAY USING THE SAME

(71) Applicant: SAMSUNG DISPLAY CO., LTD., Yongin-City (KR)

(72) Inventor: Yang-Wan KIM, Yongin-City (KR)

(21) Appl. No.: 14/505,881

(22) Filed: Oct. 3, 2014

(30) Foreign Application Priority Data
Oct. 7, 2013 (KR) 10-2013-0118971

(51) Int. Cl. G09G 3/32; H01L 27/32

(52) U.S. Cl. CPC G09G 3/3225; H01L 27/3276; H01L 27/3262
USPC 345/76; 257/40

(57) ABSTRACT

A pixel includes an organic light emitting diode, a first transistor, and a second transistor. The first transistor establishes a first current path between a first node coupled to a first power source and a second node coupled to the organic light emitting diode. The second transistor establishes a second current path between the first and second nodes. The first and second transistors are coupled in parallel.

### CROSS-REFERENCE TO RELATED APPLICATION

Korean Patent Application No. 10-2013-0118971, filed on Oct. 7, 2013, and entitled, “Pixel And Organic Light Emitting Display Using The Same,” is incorporated by reference herein in its entirety.

### BACKGROUND

1. Field

One or more embodiments described herein relate to display device.

2. Description of the Related Art

A variety of flat panel displays have been developed. Examples include liquid crystal displays, organic light emitting displays, and plasma display panels. Organic light emitting displays generated images using organic light emitting diodes that emit light based on a recombination of electrons and holes in an active layer. These displays have fast response speeds and low power consumption.

### SUMMARY

In accordance with one embodiment, a pixel includes an organic light emitting diode (OLED); a first transistor to establish a first current path between a first node coupled to a first power source and a second node coupled to the OLED; and a second transistor to establish a second current path between the first and second nodes, wherein the first and second transistors are coupled in parallel.

A channel width of the second transistor may be substantially equal to or wider than a channel width of the first transistor. Gate electrodes of the first and second transistors may be coupled to a third node.

The pixel may include a third transistor coupled between the second transistor and second node, the third transistor to turn on when a scan signal is supplied to a current scan line; a fourth transistor coupled between the second and third nodes, the fourth transistor to turn on when the scan signal is supplied to the current scan line; a fifth transistor coupled between a data line and the first node, the fifth transistor to turn on when the scan signal is supplied to the current scan line; and a storage capacitor coupled between the third node and first power source.

The pixel may include a sixth transistor coupled between the third node and an initialization power source, the sixth transistor to turn on when the scan signal is supplied to a previous scan line. The initialization power source may be set to a voltage lower than a data signal supplied to the data line.

The pixel may include a seventh transistor coupled between the first power source and first node, the seventh transistor to turn off when an emission control signal is supplied to an emission control line and to turn on when the emission control signal is not supplied to the emission control line; and an eighth transistor coupled between the second node and an anode electrode of the OLED, the eighth transistor to turn off when the emission control signal is supplied to the emission control line and to turn on when the emission control signal is not supplied to the emission control line. The turn-on period of the third transistor may not overlap the turn-on period of the seventh transistor.

In accordance with another embodiment, an organic light emitting display includes a scan driver configured to supply a scan signal to scan lines; a data driver configured to supply a data signal to data lines; and a plurality of pixels in an area defined by the scan and data lines, wherein each pixel positioned on an i-th horizontal line includes: an organic light emitting diode (OLED); a first transistor to establish a first current path between a first node coupled to a first power source and a second node coupled to the OLED; and a second transistor to establish a second current path between the first and second nodes, the first and second transistors coupled in parallel.

Current may flow through the first and second current paths during a period in which the threshold voltage of the first transistor is compensated. Current may flow through the first path during a period in which the OLED emits light. A channel width of the second transistor may be substantially equal to or wider than a channel width of the first transistor.

Gate electrodes of the first and second transistors may be coupled to a third node. Each pixel on the i-th horizontal line may include a third transistor coupled between the second transistor and the second node, the third transistor to turn on when a scan signal is supplied to a current scan line; a fourth transistor coupled between the second and third nodes, the fourth transistor to turn on when the scan signal is supplied to the current scan line; a fifth transistor coupled between a data line and the first node, the fifth transistor to turn on when the scan signal is supplied to the current scan line; and a storage capacitor coupled between the third node and first power source.

The display may include a sixth transistor coupled between the third node and an initialization power source, the sixth transistor to turn on when the scan signal is supplied to a previous scan line. The current scan line may be an i-th scan line, and the previous scan line may be an (i−1)-th scan line. The initialization power source may be set to a voltage lower than a data signal supplied to the data line.

The scan driver may supply an emission control signal to emission control lines parallel to the scan lines. Each pixel on the i-th horizontal line may include a seventh transistor coupled between the first power source and first node, the seventh transistor to turn off when the emission control signal is supplied to an i-th emission control line and to turn on when the emission control signal is not supplied to the i-th emission control line; and an eighth transistor coupled between the second node and an anode electrode of the OLED, the eighth transistor to turn off when the emission control signal is supplied to the i-th emission control line and to turn on when the emission control signal is not supplied to the i-th emission control line. The emission control signal may be supplied to the i-th emission control line to overlap the scan signal supplied supplied to the (i−1)-th and i-th scan lines.

### BRIEF DESCRIPTION OF THE DRAWINGS

Features will become apparent to those of skill in the art by describing in detail exemplary embodiments with reference to the attached drawings in which:

FIG. 1 illustrates an embodiment of an organic light emitting display;

FIG. 2 illustrates an embodiment of a pixel;

FIG. 3 illustrates an embodiment of a driving waveform for the pixel; and

FIG. 4 illustrates an example of a current path during a light-emitting period.

### DETAILED DESCRIPTION

Example embodiments are described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

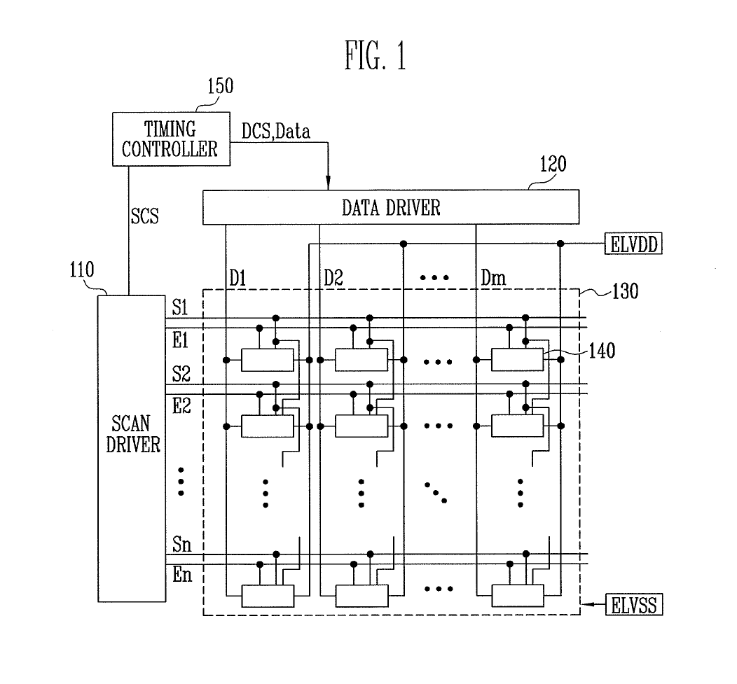

FIG. 1 illustrates an embodiment of an organic light emitting display which includes a pixel unit 130 having pixels 140 respectively positioned at intersection portions of scan lines S1 to Sn and data lines D1 to Dm. Also included is a scan driver 110 to drive scan lines S1 to Sn and emission control lines E1 to En, a data driver 120 to drive data lines D1 to Dm, and a timing controller 150 to control scan driver 110 and data driver 120.

The timing controller 150 generates a data driving control signal DCS and a scan driving control signal SCS, corresponding to synchronization signals supplied from an external source. The data driving control signal DCS generated in timing controller 150 is supplied to data driver 120. The scan driving control signal SCS generated in timing controller 150 is supplied to scan driver 110. The timing controller 150 supplies, to data driver 120, data Data supplied from an external source.

The scan driver 110 receives scan driving control signal SCS from timing controller 150. The scan driver 110 generates a scan signal based on scan driving control signal SCS and supplies the scan signal to scan lines S1 to Sn. For example, scan driver 110 may progressively supply the scan signal to scan lines S1 to Sn. The scan driver 110 generates an emission control signal in response to the scan driving control signal SCS, and supplies the emission control signal to emission control lines E1 to En. For example, scan driver 110 may progressively supply an emission control signal to emission control lines E1 to En. The scan signal may be set to a voltage (e.g., a low voltage) at which transistors in pixels 140 turn on. The emission control signal may be set to a voltage (e.g., a high voltage) at which the transistors in pixels 140 turn off.

The width of the emission control signal may be identical to or wider than the scan signal. For example, the emission control signal supplied to an i-th (i is a natural number) emission control line Ei may be supplied to overlap the scan signal supplied to (i−1)-th and i-th scan lines Si−1 and Si.

The data driver 120 receives the data driving control signal DCS from timing controller 150. The data driver 120 generates a data signal based on the data driving control signal DCS and supplies the generated data signal to the data lines D1 to Dm to be synchronized with the scan signal.

The pixel unit 130 receives first and second power sources ELVDD and ELVSS from an external source, and the first and second power sources ELVDD and ELVSS are supplied to pixels 140. Each pixel 140 generates light with a luminance based on the amount of current flowing from the first power source ELVDD to the second power source ELVSS, via an organic light emitting diode (OLED), based on the data signal. Meanwhile, each pixel 140 compensates for a threshold voltage using first and second current paths and supplies current to the OLED using the first path.

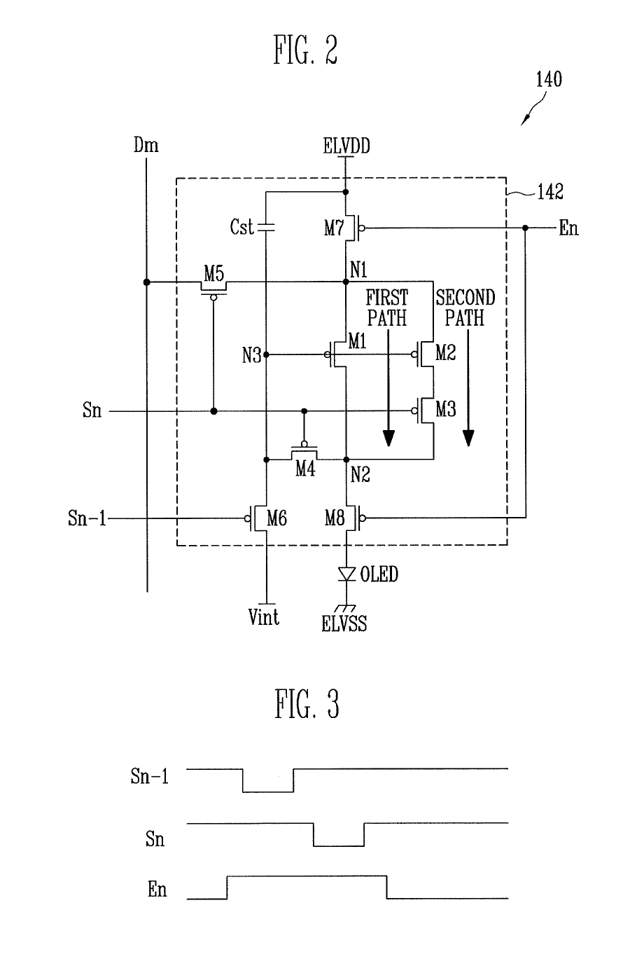

FIG. 2 illustrates an embodiment of a pixel, which, for example, may correspond in structure to the pixels in FIG. 1. For convenience of illustration, the pixel in FIG. 2 is illustrated to be coupled to an m-th data line Dm, n-th scan line Sn (current scan line), (n−1)-th scan line Sn−1 (previous scan line), and n-th emission control line En.

Referring to FIG. 2, pixel 140 includes an OLED and a pixel circuit 142. The pixel circuit 142 is coupled to data line Dm, scan lines Sn−1 and Sn, and emission control line En to control the amount of current supplied to the OLED.

An anode electrode of the OLED is coupled to pixel circuit 142, and a cathode electrode of the OLED is coupled to second power source ELVSS. The second power source ELVSS is set to a voltage lower than that of the first power source ELVDD. The OLED generates light with a luminance based on the amount of current supplied from pixel circuit 142.

The pixel circuit 142 has first and second paths along which current flows through the OLED. The pixel circuit 142 supplies the current, using the first and second paths, during a period in which the threshold voltage first transistor M1 is compensated. The pixel circuit 142 supplies the current, using the first path, during a period in which the OLED emits light.

When the current is supplied to third node N3, using the first and second paths during the threshold voltage compensation period, a desired voltage is applied to the third node N3 within a fast time. That is, in the present embodiment, a large amount of current is supplied using the first and second paths during the threshold voltage compensation period. Accordingly, the threshold voltage can be stably compensated.

In the present embodiment, the current is supplied to the OLED using the first path during the emission period. When the current is supplied to the OLED using the first path, the amount of the current supplied to the OLED is limited, thereby increasing the data swing range of a data signal. For example, the amount of the current flowing through the OLED may be limited to correspond to a voltage variation of the third node N3. As a result, the data swing range of the data signal may be increased. In this case, the current variation between driving transistors MD having a characteristic variation (distribution) is decreased, thereby displaying a uniform image.

The pixel circuit 142 includes first to eighth transistors M1 to M8 and a storage capacitor Cst. A first electrode of first transistor M1 is coupled to a first node N1. A second electrode of first transistor M1 is coupled to a second node N2. A gate electrode of first transistor M1 is coupled to third node N3. The first transistor M1 controls the amount of current flowing from first node N1 to second node N2, based on the voltage applied to third node N3. The first transistor M1 forms the first path along which the current can flow. The first node N1 is coupled to the first ELVDD via seventh transistor M7. The second node N2 is coupled to the OLED via eighth transistor M8.

A first electrode of second transistor M2 is coupled to first node N1. A second electrode of second transistor M2 is coupled to a first electrode of third transistor M3. A gate electrode of second transistor M2 is coupled to third node N3. For example, the second transistor M2 is coupled in parallel to first transistor M1, and controls the amount of current flowing from first node N1 to third transistor M3 based on the voltage of third node N3. The second transistor M2 forms the second path along which the current can flow.

Meanwhile, in the present embodiment, the first path is used as a current path during the threshold voltage compensation period and the period in which the current is supplied to the OLED. The second path is used as a current path during the threshold voltage compensation period. The channel widths of first and second transistors M1 and M2 may be controlled, so that a large amount of current can flow along the second path rather than the first path. Accordingly, the data swing range of the data signal may be increased and, simultaneously, the threshold voltage may be stably compensated. For example, the channel width of the second transistor M2 may be identical to or wider than the channel width of the first transistor M1.

The third transistor M3 is coupled between second transistor M2 and second node N2. A gate electrode of third transistor M3 is coupled to the n-th scan line Sn. The third transistor M3 is positioned on the second path. The third transistor M3 turns on when a scan signal is supplied to the n-th scan line Sn, to allow second transistor M2 and second node N2 to be electrically coupled to each other.

The fourth transistor M4 is coupled between the second and third nodes N2 and N3. A gate electrode of the fourth transistor M4 is coupled to the n-th scan line Sn. The fourth transistor M4 is turned on when the scan signal is supplied to the n-th scan line Sn, to allow the second and third nodes N2 and N3 to be electrically coupled.

The fifth transistor M5 is coupled between data line Dm and first node N1. A gate electrode of fifth transistor M5 is coupled to n-th scan line Sn. The fifth transistor M5 is turned on when the scan signal is supplied to the n-th scan line Sn, to allow data line Dm and first node N1 to be electrically coupled to each other.

The sixth transistor M6 is coupled to third node N3 and an initialization power source Vint. A gate electrode of sixth transistor M6 is coupled to the (n−1)-th scan line Sn−1. The sixth transistor M6 is turned on when the scan signal is supplied to the (n−1)-th scan line Sn−1, to supply the voltage of the initialization power source Vint to the third node N3. The initialization power source Vint may be set to a voltage lower than the data signal.

A first electrode of the seventh transistor M7 is coupled to the first power source ELVDD. A second electrode of seventh transistor M7 is coupled to first node N1. A gate electrode of seventh transistor M7 is coupled to emission control line En. The seventh transistor M7 is turned off when an emission control signal is supplied to emission control line En, and is turned on when the emission control signal is not supplied.

A first electrode of eighth transistor M8 is coupled to second node N2. A second electrode of eighth transistor M8 is coupled to the anode electrode of the OLED. A gate electrode of eighth transistor M8 is coupled to emission control line En. The eighth transistor M8 is turned off when the emission control signal is supplied to the emission control line En, and is turned on when the emission control signal is not supplied.

The storage capacitor Cst is coupled between first power source ELVDD and third node N3. The storage capacitor Cst stores the voltage of a data signal applied to the third node N3.

FIG. 3 illustrates an embodiment of a waveform diagram to be supplied to the pixel in FIG. 2. Referring to FIG. 3, the emission control signal is first supplied to the emission control line En, so that seventh and eighth transistors M7 and M8 turn off. When seventh transistor M7 turns off, first power source ELVDD and first node N1 are electrically decoupled from each other. When eighth transistor M8 turns off, second node N2 and the OLED are electrically decoupled from each other. Thus, pixel 140 is set in a non-emission state during the period in which the emission control signal is supplied to emission control line En.

Subsequently, scan signal is supplied to the (n−1)-th scan line Sn−1 to turn on sixth transistor M6. When sixth transistor M6 turns on, the voltage of the initialization power source Vint is supplied to third node N3.

After the voltage of the initialization power source Vint is supplied to third node N3, the scan signal is supplied to the n-th scan line Sn. When the scan signal is supplied to the n-th scan line Sn, third, fourth and fifth transistors M3, M4 and M5 are turned on.

When third transistor M3 turns on, second transistor M2 and second node N2 are electrically coupled to each other. When fourth transistor M4 turns on, second and third nodes N2 and N3 are electrically coupled to each other. When second and third nodes N2 and N3 are electrically coupled to each other, the first and second transistors M1 and M2 are diode-coupled.

When fifth transistor M5 turns on, data line Dm and first node N1 are electrically coupled to each other. Then, the data signal from data line Dm is supplied to first node N1. In this case, third node N3 is initialized with the voltage of initialization power source Vint and first and second transistors M1 and M2 turn on. When first and second transistors M1 and M2 turn on, current flows to third node N3 via the first and second paths. In this case, the voltage of the third node N3 is approximately increased to a voltage obtained by subtracting the threshold voltage of the first transistor M1 from the voltage of the data signal. The storage capacitor Cst stores the voltage applied to the third node N3.

Meanwhile, current is supplied to third node N3 via the first and second paths, based on the voltage of the data signal applied to the first node N1 during the period in which the scan signal is supplied to n-th scan line Sn. When current is supplied using the first and second paths, the voltage of third node N3 may increase within a fast time. Accordingly, the threshold voltage may be stably compensated.

After a predetermined voltage is stored in storage capacitor Cst, supply of the emission control signal to emission control line En is stopped to turn on seventh and eighth transistors M7 and M8. When seventh transistor M7 turns on, the first power source ELVDD and first node N1 are electrically coupled to each other. When eighth transistor M8 turns on, second node N2 and the OLED are electrically coupled to each other.

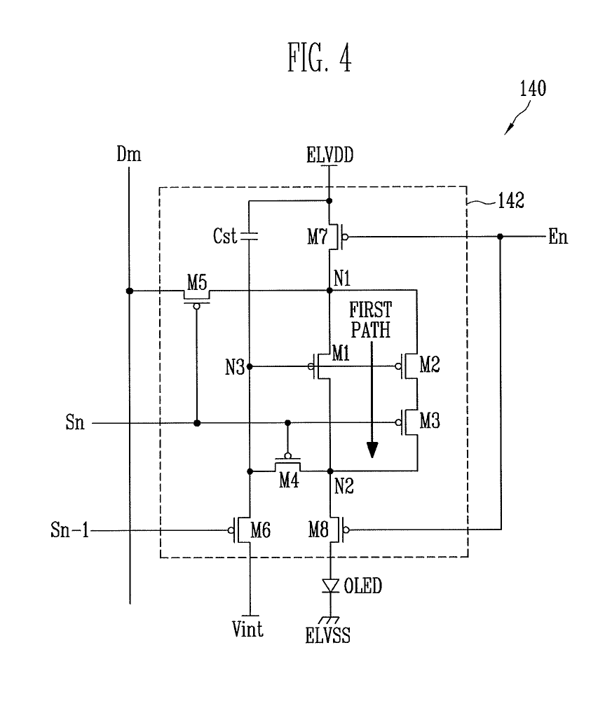

In this case, first transistor M1 controls the amount of the current flowing from the first power source ELVDD to the second power source ELVSS, via the organic light emitting diode OLED, based on the voltage of the third node N3. For example, FIG. 4 illustrates a predetermined current supplied to the OLED via the first path.

In other words, in the present embodiment, the current supplied to the OLED is supplied through the first path during the period in which pixel 140 emits light. In this case, the amount of the current flowing through the OLED is controlled based on the voltage of the third node N3. Accordingly, the data swing range of the data signal may be increased. When the data swing range of the data signal increases, the current variation between driving transistors M1 having a characteristic variation (distribution) is decreased, thereby display a more uniform image.

In the aforementioned embodiments, the transistors are shown as PMOS transistors. In other embodiment, one or more of the transistors may be NMOS transistors.

In one embodiment, the OLED may generate red, green, and blue light corresponding to the amount of current supplied from the driving transistor, or may generate white light corresponding to the amount of the current supplied from the driving transistor. In a case where the organic light emitting diode OLED generates white light, a color image may be implemented using a separate color filter or the like.

By way of summation and review, an organic light emitting display includes a plurality of pixels arranged in a matrix form at intersection portions of a plurality of data lines, a plurality of scan lines and a plurality of power lines. Each pixel generally includes an organic light emitting diode, two or more transistors each having a driving transistor, and one or more capacitors.

The organic light emitting display has low power consumption. However, in an organic light emitting display, the amount of current flowing through the organic light emitting diode may change depending on a variation in a characteristic (e.g., the threshold voltage) of the driving transistor. Therefore, display non-uniformity may result. The characteristic of a driving transistor may change, for example, depending on a fabrication process variable of the driving transistor in each pixel. Accordingly, there has been proposed a method of adding, to each pixel, a compensation circuit including a plurality of transistors and capacitors.

The compensation circuit allows the driving transistor to be diode-coupled during the supply period of a scan signal, thereby compensating for the variation in the threshold voltage of the driving transistor. However, in a case where a panel of the organic light emitting display is driven with the high resolution and/or high driving frequency, the supply time of a scan signal is shortened. Accordingly, it may be difficult to compensate for the threshold voltage of a driving transistor.

In accordance with one or more embodiments of the pixel and organic light emitting display, a current path is formed using first and second paths during a period in which the threshold voltage of the driving transistor is compensated. Also, a current path is formed using the first path during the period in which the organic light emitting diode emits light. Thus, a large amount of current may flow using the first and second paths during the period in which the threshold voltage is compensated. Accordingly, the threshold voltage may be stably compensated during a predetermined time.

If current is supplied using only the first path during the period in which the organic light emitting diode emits light, the amount of current flowing through the organic light emitting diode, corresponding to the voltage of the gate electrode of the driving transistor, is limited. In this case, the data swing range of the data signal is increased. Accordingly, the current variation between the driving transistors may be decreased in each pixel, thereby displaying a uniform image.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly, it will be understood by those of skill in the art that various changes in form and details may be made without departing from the spirit and scope of the present invention as set forth in the following claims.

What is claimed is:

1. A pixel, comprising:
an organic light emitting diode (OLED);
a first transistor to establish a first current path between a first node coupled to a first power source and a second node coupled to the OLED; and
a second transistor to establish a second current path between the first and second nodes, wherein the first and second transistors are coupled in parallel.

2. The pixel as claimed in claim 1, wherein a channel width of the second transistor is substantially equal to or wider than a channel width of the first transistor.

3. The pixel as claimed in claim 1, wherein gate electrodes of the first and second transistors are coupled to a third node.

4. The pixel as claimed in claim 3, further comprising:
a third transistor coupled between the second transistor and the second node, the third transistor to turn on when a scan signal is supplied to a current scan line;
a fourth transistor coupled between the second and third nodes, the fourth transistor to turn on when the scan signal is supplied to the current scan line;
a fifth transistor coupled between a data line and the first node, the fifth transistor to turn on when the scan signal is supplied to the current scan line; and
a storage capacitor coupled between the third node and first power source.

5. The pixel as claimed in claim 4, further comprising:
a sixth transistor coupled between the third node and an initialization power source, the sixth transistor to turn on when the scan signal is supplied to a previous scan line.

6. The pixel as claimed in claim 5, wherein the initialization power source is set to a voltage lower than a data signal supplied to the data line.

7. The pixel as claimed in claim 4, further comprising:
a seventh transistor coupled between the first power source and first node, the seventh transistor to turn off when an emission control signal is supplied to an emission control line and to turn on when the emission control signal is not supplied to the emission control line; and
an eighth transistor coupled between the second node and an anode electrode of the OLED, the eighth transistor to turn off when the emission control signal is supplied to the emission control line and to turn on when the emission control signal is not supplied to the emission control line.

8. The pixel as claimed in claim 7, wherein the turn-on period of the third transistor does not overlap the turn-on period of the seventh transistor.

9. An organic light emitting display, comprising:
a scan driver configured to supply a scan signal to scan lines;
a data driver configured to supply a data signal to data lines; and
a plurality of pixels in an area defined by the scan and data lines,
wherein each pixel positioned on an i-th horizontal line includes:
an organic light emitting diode (OLED);
a first transistor to establish a first current path between a first node coupled to a first power source and a second node coupled to the OLED; and
a second transistor to establish a second current path between the first and second nodes, the first and second transistors coupled in parallel.

10. The display as claimed in claim 9, wherein current flows through the first and second current paths during a period in which the threshold voltage of the first transistor is compensated.

11. The display as claimed in claim 9, wherein current flows through the first path during a period in which the OLED emits light.

12. The display as claimed in claim 9, wherein a channel width of the second transistor is substantially equal to or wider than a channel width of the first transistor.

13. The display as claimed in claim 9, wherein gate electrodes of the first and second transistors are coupled to a third node.

14. The display as claimed in claim 13, wherein each pixel on the i-th horizontal line includes:
a third transistor coupled between the second transistor and the second node, the third transistor to turn on when a scan signal is supplied to a current scan line;
a fourth transistor coupled between the second and third nodes, the fourth transistor to turn on when the scan signal is supplied to the current scan line;
a fifth transistor coupled between a data line and the first node, the fifth transistor to turn on when the scan signal is supplied to the current scan line; and
a storage capacitor coupled between the third node and first power source.

15. The display as claimed in claim 14, further comprising:
a sixth transistor coupled between the third node and an initialization power source, the sixth transistor to turn on when the scan signal is supplied to a previous scan line.

16. The display as claimed in claim 15, wherein:
the current scan line is an i-th scan line, and
the previous scan line is an (i−1)-th scan line.

17. The display as claimed in claim 15, wherein the initialization power source is set to a voltage lower than a data signal supplied to the data line.

18. The display as claimed in claim 9, wherein the scan driver is to supply an emission control signal to emission control lines parallel to the scan lines.

19. The display as claimed in claim 18, wherein each pixel on the i-th horizontal line includes:
a seventh transistor coupled between the first power source and first node, the seventh transistor to turn off when the emission control signal is supplied to an i-th emission control line and to turn on when the emission control signal is not supplied to the i-th emission control line; and
an eighth transistor coupled between the second node and an anode electrode of the OLED, the eighth transistor to turn off when the emission control signal is supplied to the i-th emission control line and to turn on when the emission control signal is not supplied to the i-th emission control line.

20. The display as claimed in claim 19, wherein the emission control signal to be supplied to the i-th emission control line is to overlap the scan signal supplied to be supplied to the (i−1)-th and i-th scan lines.
